(19) United States
(12) Patent Application Publication
(10) Pub. No.: US 2026/0093878 A1
(43) Pub. Date: Apr. 2, 2026

(54) Method for estimating the dispatching time of semiconductor machine

(71) Applicant: United Semiconductor (Xiamen) Co, Ltd., Xiamen (CN)

(72) Inventors: ZHEN YU SUI, Shamen City (CN); TAO LIU, Singapore (SG); XIN ZHANG, Shamen City (CN); WEN YI TAN, Xiamen (CN)

(73) Assignee: United Semiconductor (Xiamen) Co, Ltd., Xiamen (CN)

(21) Appl. No.: 18/923,626

(22) Filed: Oct. 22, 2024

(30) Foreign Application Priority Data
Sep. 27, 2024 (CN) 202411360690.1

(51) Int. Cl. G06F 30/30

(52) U.S. Cl. CPC G06F 30/30

(57) ABSTRACT

The invention provides a method for estimating the dispatching time of semiconductor machine, which is characterized by comprising the following steps: firstly, providing a semiconductor machine with a plurality of chambers, then providing a plurality of lot wafer groups, wherein each lot wafer group comprises a plurality of wafers, then sending the lot wafer groups to the semiconductor machine for a plurality of processes, and according to the process conditions of the lot wafer groups in the semiconductor machine, a simulated process flow chart is developed by a system, and a dispatching time is calculated according to the simulated process flow chart, wherein the simulated process flow chart developed by the system is obtained based on a constraint programming (CP) algorithm.

### BACKGROUND OF THE INVENTION

### 1. Field of the Invention

The invention relates to the field of semiconductor manufacturing, in particular to a method for estimating the dispatching time of a semiconductor machine, which can improve the use efficiency of the machine and reduce the total manufacturing time.

### 2. Description of the Prior Art

The manufacturing process of semiconductor wafer is quite complicated, involving many precise steps. Each wafer needs to go through multiple processes, which are carried out in different special machines. Each process corresponds to different machines, and some machines even have multiple chambers. When the process of one lot (or batch) of wafers in the semiconductor machine is completed, the next lot of wafers can be sent to the semiconductor machine to continue the process. The above step of sending a lot of wafers to the semiconductor machine is called dispatching step, and the earliest time when a lot of semiconductor wafers can be sent to the semiconductor machine is called dispatching time. Therefore, the dispatch time of the next lot of wafers can be accurately predicted, which will help to reduce the idle time between processes and improve the efficiency of processes.

However, there are many uncertain factors in the semiconductor manufacturing process, and the most common one is the process error. These errors may be caused by machine failure, material defects, environmental changes and other reasons, which may lead to the process delay of some machines. Once the delay occurs, the original scheduled dispatching time of the next lot of wafers will be disrupted, which will affect the operation efficiency of the whole production line. At this point, the manufacturer must respond quickly and recalculate the dispatch time of the next lot of wafers so that the production line can resume normal operation as soon as possible.

However, it is not easy to recalculate the dispatch time of the next lot of wafers. The complexity of this task stems from the fact that it involves many interrelated factors, including the machine processing time, which machine is delayed, the number of wafers, the wafer processing requirements, etc. These factors interact with each other, making it a very challenging task to recalculate the dispatching time of the next lot of wafers.

### SUMMARY OF THE INVENTION

In view of the above problems, the present invention provides a method for estimating dispatch time of a semiconductor machine, comprising: providing a semiconductor machine, wherein the semiconductor machine comprises a plurality of chambers, providing a plurality of lots of wafer groups, each lot of wafer groups containing a plurality of wafers, sending the plurality of wafer groups to the semiconductor machine for multiple processes, and developing a simulated process flow chart by a system according to the process conditions of the wafer groups in the semiconductor machine, and a dispatch time is calculated according to the simulated process flow chart, wherein the simulated process flow chart developed by the system is obtained based on a constraint programming (CP) algorithm.

The invention provides a wafer dispatching estimating method which is more accurate and beneficial to automation. Calculating the wafer dispatch time (that is, the time when the next lot of wafers can be dispatched to the machine) in the conventional steps is usually based on the data stored in the past process database. However, it is not accurate enough to calculate the end time of the process based on the past data, nor can it reflect the status of the process in time to make adjustments. The invention is characterized in that when each lot of wafers enter the preparation area of the semiconductor machine, various constraint conditions are input into the system, such as the number of wafers, the process required for wafers, the time spent in the process in each chamber, etc., and an optimal solution is obtained by a constraint programming (CP) algorithm and a solver. And the optimal solution is output and the production time sequence of each wafer and the graphical simulated process flow chart are obtained, so as to accurately calculate the process end time of this lot of wafers in the semiconductor machine and facilitate the assignment of the next lot of wafers to the semiconductor machine. According to the invention, the original process time calculation based on the whole lot of wafers can be further accurate to calculate the process time based on each wafer in each lot of wafer groups. At the same time, the invention uses systematic calculation to replace manual calculation to process a large number of complex data, which is more conducive to automatic production. In addition, when some machines are delayed for various reasons, the system can immediately respond and quickly re-establish a new production time sequence and a graphical simulated process flow chart, effectively improving production efficiency.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

In order to make the following easier to understand, readers can refer to the drawings and their detailed descriptions at the same time when reading the present invention. Through the specific embodiments in the present specification and referring to the corresponding drawings, the specific embodiments of the present invention will be explained in detail, and the working principle of the specific embodiments of the present invention will be expounded. In addition, for the sake of clarity, the features in the drawings may not be drawn to the actual scale, so the dimensions of some features in some drawings may be deliberately enlarged or reduced.

FIG. 1 shows a schematic diagram of a semiconductor machine with multiple chambers.

FIG. 2 is a schematic flow chart of performing semiconductor steps in an embodiment.

FIG. 3 shows a flow chart for establishing the dispatching sequence of wafers according to another embodiment of the present invention.

FIG. 4 shows two examples of constraint condition tables.

FIG. 5 shows an example of a simulated process flow chart.

FIG. 6 is a schematic diagram showing a simulated process flow chart suitable for a continuous process of a plurality of semiconductor machines.

### DETAILED DESCRIPTION

To provide a better understanding of the present invention to users skilled in the technology of the present invention, preferred embodiments are detailed as follows. The preferred embodiments of the present invention are illustrated in the accompanying drawings with numbered elements to clarify the contents and the effects to be achieved.

Please note that the figures are only for illustration and the figures may not be to scale. The scale may be further modified according to different design considerations. When referring to the words “up” or “down” that describe the relationship between components in the text, it is well known in the art and should be clearly understood that these words refer to relative positions that can be inverted to obtain a similar structure, and these structures should therefore not be precluded from the scope of the claims in the present invention.

Although the present invention uses the terms first, second, third, etc. to describe elements, components, regions, layers, and/or sections, it should be understood that such elements, components, regions, layers, and/or sections should not be limited by such terms. These terms are only used to distinguish one element, component, region, layer and/or block from another element, component, region, layer and/or block. They do not imply or represent any previous ordinal number of the element, nor do they represent the arrangement order of one element and another element, or the order of manufacturing methods. Therefore, the first element, component, region, layer or block discussed below can also be referred to as the second element, component, region, layer or block without departing from the specific embodiments of the present invention.

The term “about” or “substantially” mentioned in the present invention usually means within 20% of a given value or range, such as within 10%, or within 5%, or within 3%, or within 2%, or within 1%, or within 0.5%. It should be noted that the quantity provided in the specification is approximate, that is, the meaning of “about” or “substantially” can still be implied without specifying “about” or “substantially”.

The terms “coupling” and “electrical connection” mentioned in the present invention include any direct and indirect means of electrical connection. For example, if the first component is described as being coupled to the second component, it means that the first component can be directly electrically connected to the second component, or indirectly electrically connected to the second component through other devices or connecting means.

Although the invention of the present invention is described below by specific embodiments, the inventive principles of the present invention can also be applied to other embodiments. In addition, in order not to obscure the spirit of the present invention, specific details are omitted, and the omitted details are within the knowledge of those with ordinary knowledge in the technical field.

Please note that in the specification of the present invention, “dispatching” refers to the process or time point when a lot (or a batch) of semiconductor wafers can be assigned to a semiconductor machine, that is, the flow of wafers outside the semiconductor machine. And “production” or “manufacturing process” refer to the process of wafer moving in the preparation area and chamber inside the semiconductor machine, or the general name of various manufacturing steps, that is, the flow of wafers inside the semiconductor machine. In order to facilitate understanding, the difference between the two is explained here first.

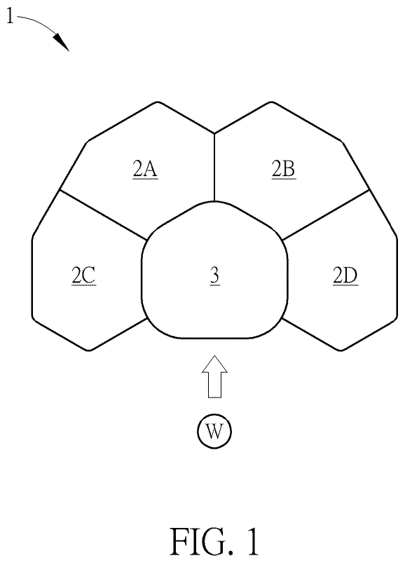

Please refer to FIG. 1, which shows a schematic diagram of a semiconductor machine with multiple chambers. As shown in FIG. 1, a semiconductor machine 1 includes a preparation area 3 connected with a plurality of chambers, which are defined as a chamber 2A, a chamber 2B, a chamber 2C and a chamber 2D respectively. After the wafer W is sent to the preparation area 3, the wafer W can be sent to different chambers according to the process sequence. Among them, it is possible to perform the same process or different processes in each chamber 2A, 2B, 2C and 2D, such as sputtering, deposition and etching, and the present invention is not limited to this. In addition, depending on the semiconductor machine, the semiconductor machine 1 may contain more or less chambers. However, the present invention relates to a dispatching estimating method suitable for semiconductor machines with multiple chambers. In the following paragraphs, the semiconductor machine 1 with four chambers shown in FIG. 1 will be described as an example.

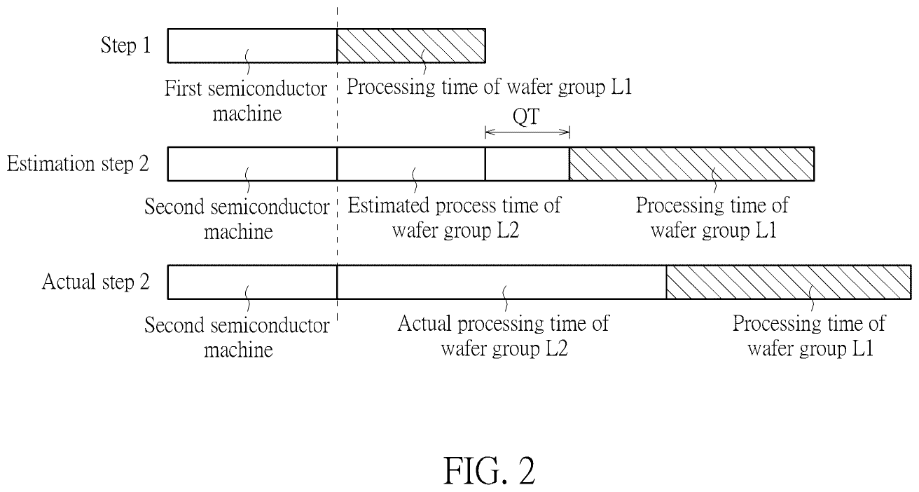

FIG. 2 is a schematic flow chart of performing semiconductor steps in an embodiment. As shown in FIG. 2, in one embodiment, step 1 shows that a lot of wafer groups L1 are being processed in a first semiconductor machine, where L1 represents a lot of wafer groups. Among them, the wafer group L1 contains a plurality of wafers, which are processed in the first semiconductor machine, and after step 1 is completed, the wafer group L1 will be sent to another semiconductor machine (that is, the second semiconductor machine) for the next process, that is, all the wafers of the wafer group L1 will be sent to the second semiconductor machine together. It is worth noting that, as shown in the estimation step 2 shown in the middle of FIG. 2, in the process of step 1, another lot of wafer groups L2 are also being processed in the second semiconductor machine, and the user needs to estimate the time when the wafer group L2 completes the process in the second semiconductor machine, and set a buffer time QT. After the wafer group L2 in the second semiconductor machine completes the process, the process of wafer group L1 begins after the buffer time QT.

However, as shown in the actual step 2 at the bottom of FIG. 2, in the semiconductor manufacturing process, various errors or unexpected situations sometimes occur, which may lead to the delay of the machine. For example, when the process time of the wafer group L2 is prolonged due to the situation of the second semiconductor machine, it will also affect the process start time of the wafer group L1 in the second semiconductor machine. At this time, it is more likely to continue to affect the time of other subsequent processes, resulting in a decline in the overall process efficiency.

In the current technology, the manufacturer will calculate the approximate time for a lot of wafers to be processed in the semiconductor machine and plan the time when the next lot of wafers will be dispatched to the semiconductor machine. The above step is called dispatching. More specifically, the manufacturer usually infers the approximate time required for each process according to the past process parameters, and then works out the appropriate buffer time QT, so that the next lot of wafers can be delivered to the semiconductor machine at the planned time (that is, the dispatch time). Among them, the calculation of dispatching time needs to consider many factors, such as the number of chambers of the semiconductor machine, the number of wafers in each lot of wafer groups, which processes each wafer needs to carry out, etc. . . All these factors will affect the dispatching time of wafers. Especially when there are many steps in the semiconductor manufacturing process, or multi-chamber semiconductor machines need to be used in the manufacturing process, the step of calculating the dispatching time will be more complicated.

However, as mentioned above, when an unexpected situation occurs in the semiconductor manufacturing process and some semiconductor machines are delayed, because the estimated process completion time of the semiconductor machines is affected by many factors, it is difficult for manufacturers to recalculate the new dispatch time manually in a short time when an unexpected situation occurs. Usually, all dispatching time can only be postponed after troubleshooting, but this is not conducive to the efficiency of the process.

In view of this, the invention proposes another method to calculate the estimated dispatch time more accurately. The main concept of the invention is to calculate the process sequence in the semiconductor machine by system simulation, and accurately calculate the completion time of this lot of wafers in the semiconductor machine according to the simulation results, so as to facilitate the arrangement of the next lot of wafer groups into the semiconductor machine. The system of the invention can display a graphical simulated process flow chart. Furthermore, the invention uses constraint programming (CP) algorithm and solver to calculate an optimal solution after inputting various constraint conditions, and then converts the optimal solution into a graphical simulated process flow chart, thereby calculating the dispatching time. Accord to that invention, the estimated process end time can be calculated in each wafer without calculating the estimate process time in the whole lot of wafers, so that the process sequence in the semiconductor machine can be estimated more accurately. In addition, it can detect the process status in real time and update the simulated process flow chart at any time. More details will be described in the following paragraphs.

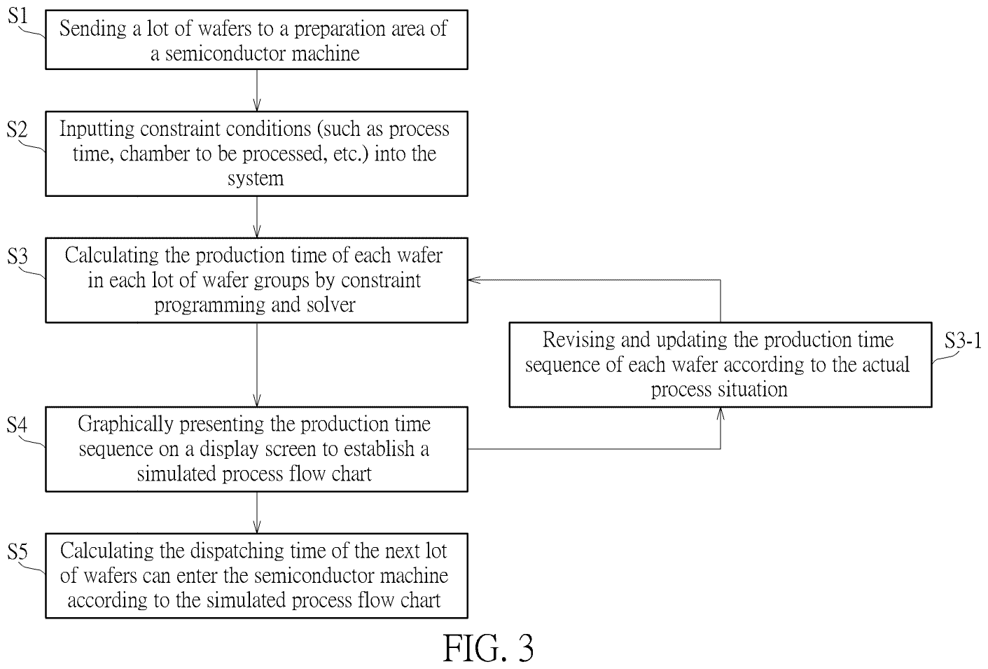

As shown in FIG. 3, FIG. 3 shows a flow chart for establishing the dispatching sequence of wafers according to another embodiment of the present invention. First, as shown in step S1, a lot of wafers are sent to the preparation area of the semiconductor machine. The wafer here is, for example, the above-mentioned wafer group L1 containing a plurality of wafers W, and the semiconductor machine is, for example, the semiconductor machine 1 with a plurality of chambers 2A to 2D as shown in FIG. 1. After the wafer group L1 is sent to the preparation area 3 of the semiconductor machine 1 (refer to FIG. 1), the semiconductor machine will send each wafer into the chamber in sequence for processing.

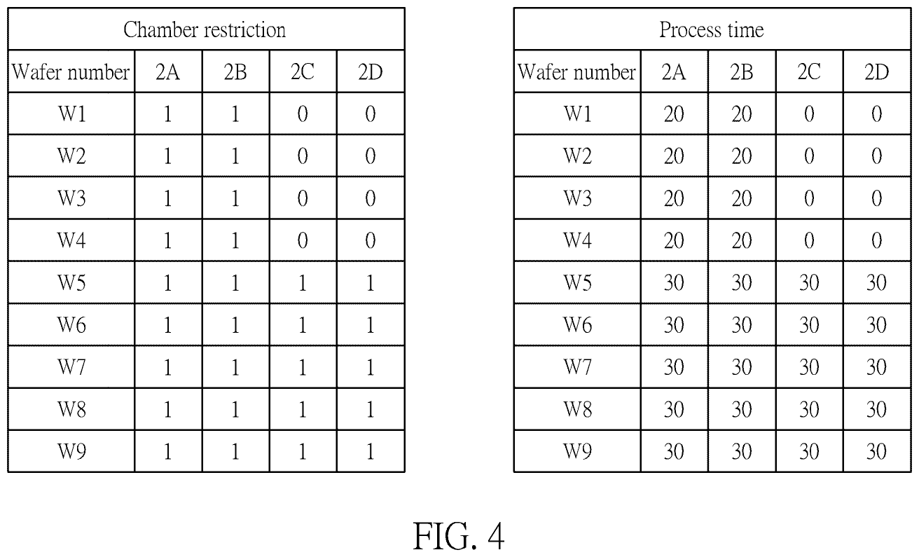

Next, as in step S2, constraint conditions (such as process time, chamber to be processed, etc.) are input into the system. More specifically, when the wafer group L1 enters the preparation area 3 of the semiconductor machine 1, the manufacturer will know in advance the number of wafers W contained in the wafer group L1, the types of processes to be manufactured, which wafers need to be processed, the time required for each process and other conditions. All these variables can be input into a system (such as a computer) by the manufacturer and converted into various constraint conditions. The constraint conditions here are, for example, various conditional expressions, for example, a wafer can only enter the chambers 2A and 2B but not the chambers 2C and 2D, or the time for a wafer to perform a process in the chamber is 30 minutes. Reference can be made to FIG. 4, which shows two examples of constraint condition tables, in which the table shown on the left side of FIG. 4 shows the chamber numbers that the wafers W1, W2, W3, W4, W5, W6, W7, W8 and W9 included in the wafer group L1 need to enter, where “1” indicates that the wafer will enter the chamber and “0” indicates that the wafer will not enter the chamber. Taking the wafer W1 as an example, the wafer W1 can enter the chamber 2A and the chamber 2B, but cannot enter the chamber 2C and the chamber 2D. Taking wafer W5 as an example, W5 can enter chamber 2A, chamber 2B, chamber 2C and chamber 2D. It is worth noting that the number of wafers in the wafer group L1 or the constraint conditions for wafers entering the chamber described here are all examples of the present invention, and other different constraint conditions may be shown in the table on the left of FIG. 4 according to different processes. For example, there may be more or fewer wafers, and the number of each wafer entering the chamber may also change. Even for the same wafer, a wafer may need to enter different chambers in sequence for multiple processes, or only one chamber needs to be selected for processes. All the above variations are within the scope of the present invention.

As for the table on the right of FIG. 4, it shows the estimated processing time of each wafer in different chambers. For example, the processing time required in chamber 2A or chamber 2B for wafer W1 is 20 minutes, and for wafer W5, the processing time required in chambers 2A-2D is 30 minutes. The constraint conditions contained in the above table are input into the system one by one. However, it can be understood that the table in FIG. 4 is only one example of the present invention, and the present invention is not limited to this.

Please continue to refer to FIG. 3, and then in step S3, the production time sequence of each wafer in each lot of wafer groups is calculated by constraint programming and solver. More specifically, after the constraint conditions are input into the system, an optimal solution is calculated under a plurality of constraint conditions by constraint programming (CP) algorithm and solver, and the optimal solution is converted into the production time sequence of each wafer. The constrained programming algorithm described here is an algorithm suitable for dealing with problems involving a large number of variables and complex constraint conditions. The core idea of constraint programming algorithm is to transform the problem into a set of variables and their constraint relations, and then use algorithm to find one or more feasible solutions on the premise of satisfying all constraint conditions. In other words, under the condition that there are multiple constraint conditions stored in the system, the solver of the system will try multiple groups of possible variables (such as enumeration, but not limited to this), and after excluding the variables that do not meet the conditions, seek an optimal solution in the remaining variable combinations. Other detailed knowledge about constrained programming algorithm belongs to the known technology in this field, therefore, these technologies are not repeated here. The constraint planning system used in this invention is IBM ILOG CPLEX Optimizers, and the solver is CP optimizer (constraint program solvers). However, the invention is not limited to this, and different brands of constraint planning systems and solvers can be used according to different requirements.

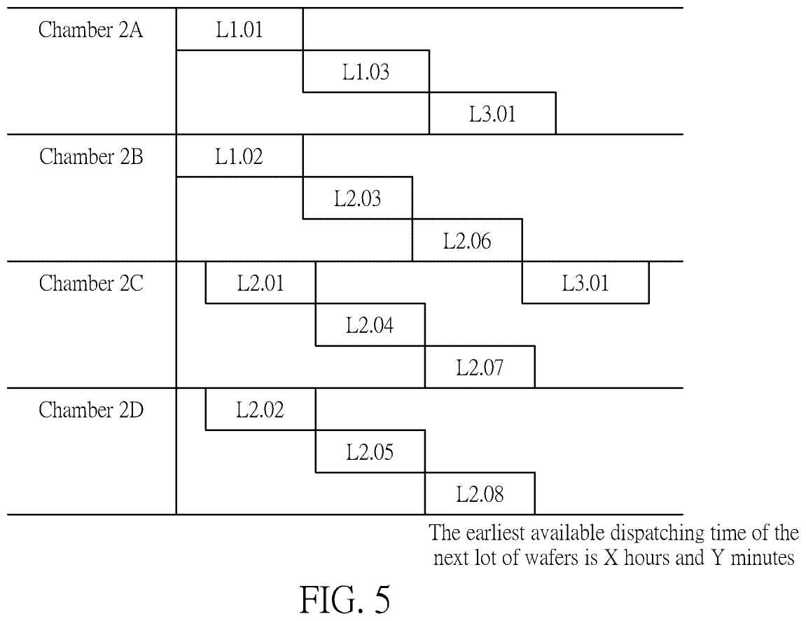

The production time sequence mentioned above is, for example, information containing data such as wafer number, scheduled process start time, scheduled process end time and chamber number scheduled for process, which shows when each wafer will enter which chamber and when it will leave the chamber. That is to say, after the system calculates the process end time of each wafer in each lot of wafer groups in the chamber, plus a buffer time (such as the time required for wafers to enter and leave the chamber), that is, the time when the next wafer can enter the chamber, listing the above data is the production time sequence. Next, as in step S4, the production time sequence is graphically presented on the display screen to establish a simulated process flow chart. Reference can be made to FIG. 5, which shows an example of a simulated process flow chart. In FIG. 5, chambers 2A-2D are displayed on a display screen, and then the wafers of each lot of wafer groups are numbered and arranged next to the corresponding chamber numbers according to the process sequence to indicate the order in which the wafers enter the chambers. For example, in the numbering in FIG. 5, the front string consisting of English and numbers represents the number of wafer groups, while the back number represents the number of wafers in this lot of wafer groups. For example, the number L1.01 represents the first wafer in the wafer group L1, the number L2.06 represents the sixth wafer in the wafer group L2, the number L3.01 represents the first wafer in the wafer group L3, and so on, the details are not repeated in this paragraph.

As shown in FIG. 3, the system converts the production time sequence into a graphical simulated process flow chart, and presents the graphical simulated process flow chart on the display screen. Next, step S5 is performed, according to the simulated process flow chart, the dispatching time when the next lot of wafers can enter the semiconductor machine is calculated. In other words, the manufacturer can present and simulate the process of each wafer in this lot of wafer groups in the semiconductor machine according to the simulated process flow chart, then calculate the process completion time of all wafers in this lot of wafer groups, and arrange the earliest time when the next lot of wafers can be allocated to the semiconductor machine (that is, the dispatch time). In this way, the estimated time results will be more accurate than the previous use of empirical data to dispatch time, and the efficiency of the process can also be improved.

In addition, the estimated process end time calculated by the system plus the preset buffer time QT is the dispatching time of the next lot of wafers, which can be displayed on the display screen. For example, the dispatching time of the next lot of wafers shown in FIG. 5 is X hours and Y minutes. Here, X and Y are suitable values.

In addition, please continue to refer to FIG. 3. Between step S3 and step S4, some wafers are processed in the chamber of the semiconductor machine. At this time, the system calculates the optimal production time sequence according to the current conditions, and converts it into a simulated process flow chart to be displayed on the display screen. However, the process conditions (i.e., the constraint conditions) may be changed due to various unexpected situations during the process, so in FIG. 3, step S3-1 is also included, that is, the production time sequence of each wafer is corrected and updated according to the actual process conditions. For example, after a fixed period of time (for example, but not limited to 5 minutes), the system will recalculate the production time sequence according to the existing constraint conditions. Or when the system detects that a specific event is met, such as when the system detects an error message in the chamber, the production time sequence of each wafer is recalculated. The new production time sequence calculated above will replace the old production time sequence, and it will be converted into a graphical simulated process flow chart according to the latest production time sequence of each wafer. In this way, the system can synchronously detect and find the sudden situation in the process, and quickly modify the simulated process flow chart according to the existing process conditions.

In addition to the constraint conditions depicted in FIG. 4, other constraint conditions may be included according to different processes, or the constraint conditions may change with the process. For example, when a chamber of a semiconductor machine fails or is delayed, conditions are input into the constraint conditions in the system. For example, when the chamber 2C fails, the system detects the event, recalculates it as a new constraint, and updates the simulated process flow chart and the earliest time when the next lot of wafers can enter the semiconductor machine (i.e., the dispatching time). In more detail, the updated simulated process flow chart shows that the wafer is no longer processed in the chamber 2C, but continues to be processed in the chambers 2A, 2B and 2D. At the same time, the system will recalculate the time when the next lot of wafers can enter the semiconductor machine.

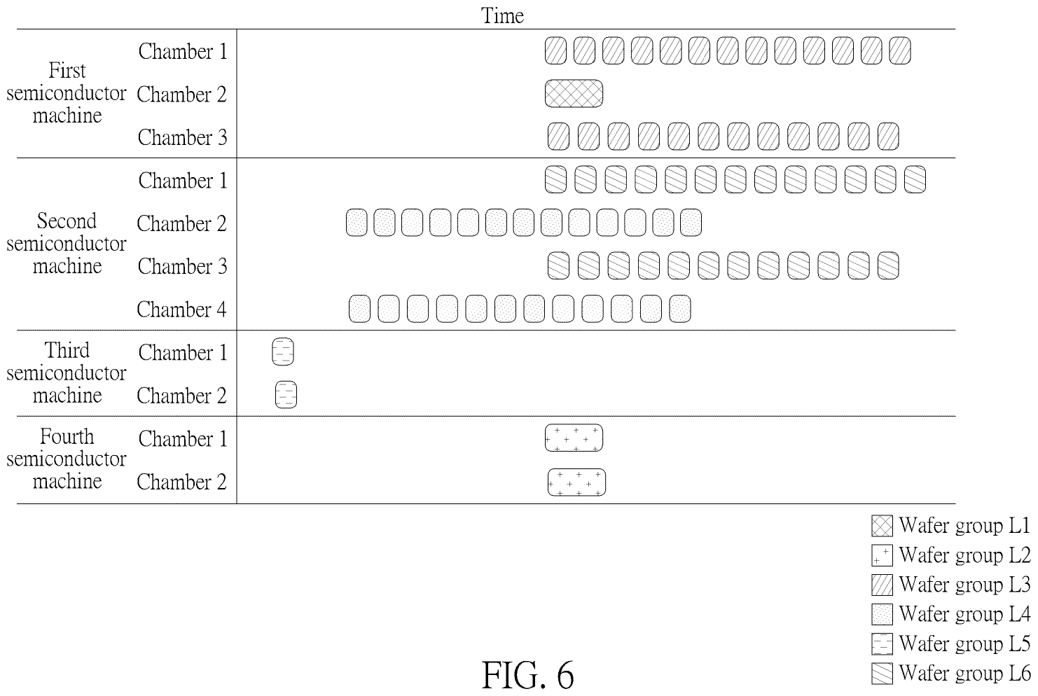

The invention is also suitable for formulating the dispatching estimating method for the continuous process of a plurality of semiconductor machines. As shown in FIG. 6, it is a schematic diagram showing a simulated process flow chart suitable for a continuous process of a plurality of semiconductor machines. As shown in FIG. 6, the longitudinal axis of the simulated process flow chart includes a first semiconductor machine, a second semiconductor machine, a third semiconductor machine and a fourth semiconductor machine, and each semiconductor machine also includes a plurality of chambers, such as chamber 1, chamber 2, chamber 3 and chamber 4. The horizontal axis of the simulated process flow chart represents time, and the simulated process flow chart also contains blocks represented by wafers of different lots of wafer groups, such as wafer group L1, wafer group L2, wafer group L3, wafer group L4, wafer group L5 and wafer group L6. Each wafer of each wafer group is represented by an independent block in FIG. 6. Because of the large number of wafers, the number of each wafer is not shown in FIG. 6 for simplicity, but it can be understood that each block represents a numbered wafer. It should be noted that the arrangement of blocks shown in FIG. 6 is only one example of the present invention, and the present invention is not limited to this. In addition, in FIG. 6, the dispatch time of each semiconductor machine can also be presented on the display screen, but it is not shown in the figure for simplicity.

As shown in FIG. 6, the simulated process flow chart developed by the invention is also suitable for the continuous process of multiple semiconductor machines. In the continuous process of multiple semiconductor machines, the process is more complicated, so it is more difficult to accurately calculate the dispatching time of each semiconductor machine. By the method provided by the invention, the system replaces manual calculation, so that the dispatching time of each semiconductor machine can be calculated more accurately, and the efficiency of the manufacturing process can be improved.

According to the above instructions and drawings, please refer to FIGS. 1 to 6. A method for estimating dispatch time of a semiconductor machine according to the present invention is provided. The method includes the following steps: providing a semiconductor machine 1, wherein the semiconductor machine 1 comprises a plurality of chambers 2A to 2D, and providing lots of wafer groups, each lot of wafer groups (for example, wafer groups L1 to L6) comprises a plurality of wafers, and sending the wafer groups to the semiconductor machine 1 for multiple processes. And according to the process conditions of a plurality of wafer groups in the semiconductor machine 1, a simulated process flow chart (FIG. 5) is drawn up or developed by a system, and an estimated process end time (dispatching time) is calculated according to the simulated process flow chart (Step S5 of FIG. 3), wherein the simulated process flow chart drawn up by the system is obtained based on a constraint programming (CP) algorithm.

In some embodiments of the present invention, each lot of wafer groups includes a plurality of wafers including a wafer number (for example, the wafer group L1 includes wafers W1-W9, but is not limited to this).

In some embodiments of the present invention, among a plurality of wafers contained in one of a plurality of wafer groups, some wafers are restricted to be processed in only one of some chambers in the semiconductor machine, while others are allowed to be processed in all chambers in the semiconductor machine (for example, as shown in FIG. 4, wafer W1 can only be processed in chamber 2A or chamber 2B, while wafer W5 can be processed in chambers 2A, 2B, 2C and 2D).

In some embodiments of the present invention, among a plurality of wafers contained in one of a plurality of wafer groups, the time spent by a part of wafers in a chamber in a semiconductor machine is defined as a first time, and the time spent by another part of wafers in a chamber in a semiconductor machine is defined as a second time, wherein the first time is different from the second time (for example, as shown in FIG. 4, the time spent on wafer W1 is 20 minutes, while the time spent on wafer W5 is 20 minutes).

In some embodiments of the present invention, where the system is based on the constraint programming algorithm, the step of simulating the process flow chart further includes inputting a plurality of constraint conditions into the system (as shown in step S2 of FIG. 3).

In some embodiments of the present invention, the constraint conditions include: the number of each chamber of the semiconductor machine corresponding to each wafer, the processing time of each wafer in each chamber, and the sequence in which each lot of wafer groups are sent to a preparation area of the semiconductor machine.

In some embodiments of the present invention, the system includes a solver, and an optimal solution is obtained according to a plurality of constraint conditions input into the system (step S3 in FIG. 3).

In some embodiments of the present invention, it further includes converting the optimal solution obtained by the solver into a simulated process flow chart and outputting the simulated process flow chart to the system (step S4 in FIG. 3).

In some embodiments of the present invention, the solver comprises CP Optimizer (constraint program solvers) of IBM ILOG CPLEX Optimizers.

In some embodiments of the present invention, the system starts to calculate and plan a production time sequence before multiple lots of wafer groups are sent to a preparation area 3 of the semiconductor machine. That is to say, before the process, the system has planned the process start and end time of each wafer in advance according to the known conditions, such as the end time of the previous lot of wafers, the number of wafers, the types of processes that wafers need to perform, etc.

In some embodiments of the present invention, the system recalculates and updates the production time sequence of each wafer for many times according to the process conditions during the process when the wafers are sent to each chamber of the semiconductor machine (as shown in step S3-1 of FIG. 3).

In some embodiments of the present invention, the system captures a plurality of parameters in the process at regular intervals, and recalculates the production time sequence of each wafer, and the newly calculated production time sequence replaces the original production time sequence. For example, the production time sequence of each wafer can be recalculated every 5 minutes to confirm whether the current production time sequence conforms to the collected parameters.

In some embodiments of the present invention, after the process meets a predetermined event, the system captures a plurality of parameters in the process and recalculates the production time sequence of each wafer, and the newly calculated production time sequence of each wafer replaces the original production time sequence. For example, the production time sequence of each wafer can be recalculated after receiving the error message.

In some embodiments of the present invention, the production time sequence of each wafer is converted into a graphical simulated process flow chart (as shown in FIG. 5 or FIG. 6) and presented on a display screen.

In some embodiments of the present invention, the dispatch time is calculated according to the simulated process flow chart after the system formulates the simulated process flow chart, and displayed on the display screen (for example, FIG. 5 shows that the dispatch time of the next lot of wafers is X hours and Y minutes).

The invention provides a wafer dispatching estimating method which is more accurate and beneficial to automation. Calculating the wafer dispatch time (that is, the time when the next lot of wafers can be dispatched to the machine) in the conventional steps is usually based on the data stored in the past process database. However, it is not accurate enough to calculate the end time of the process based on the past data, nor can it reflect the status of the process in time to make adjustments. The invention is characterized in that when each lot of wafers enter the preparation area of the semiconductor machine, various constraint conditions are input into the system, such as the number of wafers, the process required for wafers, the time spent in the process in each chamber, etc., and an optimal solution is obtained by a constraint programming (CP) algorithm and a solver. And the optimal solution is output and the production time sequence of each wafer and the graphical simulated process flow chart are obtained, so as to accurately calculate the process end time of this lot of wafers in the semiconductor machine and facilitate the assignment of the next lot of wafers to the semiconductor machine. According to the invention, the original process time calculation based on the whole lot of wafers can be further accurate to calculate the process time based on each wafer in each lot of wafer groups. At the same time, the invention uses systematic calculation to replace manual calculation to process a large number of complex data, which is more conducive to automatic production. In addition, when some machines are delayed for various reasons, the system can immediately respond and quickly re-establish a new production time sequence and a graphical simulated process flow chart, effectively improving production efficiency.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for estimating dispatch time of a semiconductor machine, comprising:
providing a semiconductor machine, wherein the semiconductor machine comprises a plurality of chambers;
providing a plurality of lots of wafer groups, each lot of wafer groups containing a plurality of wafers;
sending the plurality of wafer groups to the semiconductor machine for multiple processes; and
developing a simulated process flow chart by a system according to the process conditions of the wafer groups in the semiconductor machine, and a dispatch time is calculated according to the simulated process flow chart, wherein the simulated process flow chart developed by the system is obtained based on a constraint programming (CP) algorithm.

2. The method for estimating dispatch time of a semiconductor machine according to claim 1, wherein each wafer in the plurality of wafers included in each lot of the wafer group includes a wafer number.

3. The method for estimating dispatch time of a semiconductor machine according to claim 1, wherein among the plurality of wafers contained in one of the plurality of wafer groups, some of the wafers is restricted to be processed only in a part of the chambers in the semiconductor machine, and the other part of the wafers is allowed to be processed in all the chambers in the semiconductor machine.

4. The method for estimating dispatch time of a semiconductor machine according to claim 1, wherein among the plurality of wafers contained in one of the plurality of wafer groups, the time spent by some of the wafers in the chamber of the semiconductor machine is defined as a first time, and the time spent by another part of the wafers in the chamber of the semiconductor machine is defined as a second time, wherein the first time is different from the second time.

5. The method for estimating dispatch time of a semiconductor machine according to claim 1, wherein the system is based on the constraint programming algorithm, and the step of establishing the simulated process flow chart further comprises:
inputting multiple constraint conditions into the system.

6. The method for estimating dispatch time of a semiconductor machine according to claim 5, wherein the constraint conditions include: the number of each chamber of the semiconductor machine corresponding to each wafer, the processing time of each wafer in each chamber, and the sequence in which each lot of wafer groups are sent to a preparation area of the semiconductor machine.

7. The method for estimating dispatch time of a semiconductor machine according to claim 6, wherein the system comprises a solver, and the system obtains an optimal solution according to the constraint conditions input into the system.

8. The method for estimating dispatch time of a semiconductor machine according to claim 7, further comprising converting the optimal solution obtained by the solver into the simulated process flow chart, and outputting the simulated process flow chart to the system.

9. The method for estimating dispatch time of a semiconductor machine according to claim 7, wherein the method for the solver to obtain the optimal solution includes under the plurality of constraint conditions, trying a plurality of possible variables by enumerating, and after excluding the unqualified variables, seeking the optimal solution in the remaining variable combinations.

10. The method for estimating dispatch time of a semiconductor machine according to claim 1, wherein the system starts calculation and plans a production time sequence of each wafer before the plurality of wafer groups are sent to a preparation area of the semiconductor machine.

11. The method for estimating dispatch time of a semiconductor machine according to claim 10, wherein when the wafers are sent to each chamber of the semiconductor machine, the system recalculates and updates the production time sequence of each wafer for many times according to the process conditions during the process.

12. The method for estimating dispatch time of a semiconductor machine according to claim 11, wherein at regular intervals in the process, the system captures a plurality of parameters in the process and recalculates the production time sequence of each wafer, and a newly calculated production time sequence replaces the original production time sequence.

13. The method for estimating dispatch time of a semiconductor machine according to claim 11, wherein the system sets a plurality of events in advance, and after the process meets the qualified events, the system captures a plurality of parameters in the process and recalculates the production time sequence of each wafer, and a newly calculated production time sequence replaces the original production time sequence.

14. The method of claim 10, wherein the production time sequence of each wafer is presented on a display screen of the system with a graphical interface, and the production time sequence displayed on the display screen is defined as the simulated process flow chart.

15. The method for estimating dispatch time of a semiconductor machine according to claim 1, wherein after the system develops the simulated process flow chart, the dispatch time is calculated according to the simulated process flow chart and displayed on a display screen.
